(19) United States
(12) Patent Application Publication
(10) Pub. No.: US 2012/0255855 A1
(43) Pub. Date: Oct. 11, 2012

(54) METHOD OF CONTROLLING LITHIUM UNIFORMITY

(75) Inventor: Erik Bjornard, Northfield, MN (US)

(73) Assignee: SAGE ELECTROCHROMICS, INC., Faribault, MN (US)

(21) Appl. No.: 13/430,005

(22) Filed: Mar. 26, 2012

Related U.S. Application Data
(60) Provisional application No. 61/472,758, filed on Apr. 7, 2011.

(51) Int. Cl. C23C 14/34; C23C 14/06

(52) U.S. Cl. 204/192.1; 204/298.02

(57) ABSTRACT

A method and apparatus for providing uniform coatings of lithium on a substrate are provided. In one aspect of the present invention is a method of selectively controlling the uniformity and/or rate of deposition of a metal or lithium in a sputter process by introducing a quantity of reactive gas over a specified area in the sputter chamber. This method is applicable to planar and rotating targets.

### CROSS REFERENCE TO RELATED APPLICATIONS

This application claims the benefit of the filing date of U.S. Provisional Patent Application No. 61/472,758 filed Apr. 7, 2011, the disclosure of which is hereby incorporated herein by reference.

### BACKGROUND OF THE INVENTION

This invention is directed to the sputtering of lithium and, in particular, to magnetron sputtering of lithium from planar or rotatable metallic lithium targets.

Sputtering is widely used for depositing thin films of material onto substrates including, for example, electrochromic devices. Generally, such a process involves ion bombarding a planar or rotatable plate of the material to be sputtered (“the target”) in an ionized gas atmosphere. Gas ions out of a plasma are accelerated towards the target consisting of the material to be deposited. Material is detached (“sputtered”) from the target and afterwards deposited on a substrate in the vicinity. The process is realized in a closed chamber, which is pumped down to a vacuum base pressure before deposition starts. The vacuum is maintained during the process to cause particles of the target material to be dislodged and deposited as a thin film on the substrate being coated.

The material to be sputtered onto the substrate is present as a coating on a target plate (the plate itself can be a rotating target plate or a planar target plate). Any material may be used for this purpose, including pure and mixed metals. Because many pure and mixed metals, or other target materials, are reactive, it is necessary to keep them away from any potentially reactive reagent.

Targets formed from lithium compounds such as Li₂CO₃ can be successfully sputtered to deposit lithium into electrochromic materials. In large scale systems, however, the RF sputtering potential required with a Li₂CO₃ target presents process problems such as non-uniformity and requires expensive equipment for generating and handling high power RF.

To overcome some of these limitations, it has been proposed to sputter lithium in its essentially pure, metallic form. One way of sputtering metallic lithium has been described in U.S. Pat. No. 5,830,336 and U.S. Pat. No. 6,039,850, the disclosures of which are hereby incorporated by reference herein in their entirety. Lithium is sputtered away from a metallic lithium target onto the electrode by means of, for example, an argon plasma that is magnetically confined in the vicinity of the target. The target is preferably AC (300 to 100 kHz, US '336) or pulsed DC powered (U.S. Pat. No. 6,039,850).

This method, it is believed, results in a well controlled way of adding lithium to a substrate. However, the method also has drawbacks: the handling and sputtering of metallic lithium targets is not straightforward due to the very oxidizing nature of lithium. It is believed that the target surface can develop a thick layer of lithium oxide. It may take a long time to remove this layer and achieve a stable sputtering condition for the target. For sputtering in general, it is well known in the art that the addition of reactive agents, such as oxygen, in the sputtering chamber may reduce the overall rate of sputtering (U.S. Pat. No. 4,769,291).

Also, the deposition step of other layers such as the electrode, which is generally performed using reactive sputtering in an oxidizing atmosphere, must be well separated from the lithiation step in order to prevent oxidation of the lithium target and electrode. Notable is that lithiation has to be performed as a separate process step. To accomplish this, it is common practice to isolate the lithium metal target material from reactive gases in the sputter chamber. One method of isolating the chamber is by incorporating locks (or lock chambers) to fully isolate the lithium from the neighboring processes. Such a method, however, requires additional manufacturing space and slows overall processing since the substrate must be carefully moved to each “lock” position and the “lock” be “pumped down” before sputtering. The presence of these locks, it is believed, greatly increases cost, and reduces overall process efficiency by requiring additional time and manufacturing floor space.

Moreover, it is believed that lithium is a highly reactive metal which is believed to corrode rapidly in the presence of reactive gases such as water, oxygen, and nitrogen. When exposed to these gases, or air in general, the surface of lithium metal reacts and blackens. This reacted, blackened target surface must be sputtered for an extended period of time to expose pure lithium metal suitable for depositing on a substrate. This “burn-in” typically takes about 8 hours in the case of a planar target. For a rotating cylindrical target this process can take up to 30 hours due to the increased surface area which needs to be cleaned. Not only do these processes take time and reduce overall processing efficiency, they reduce the amount of available target material which can be deposited on a substrate. Less material means the sputtering chamber has to be opened and replaced with a new target, again reducing overall process efficiency.

### BRIEF SUMMARY OF THE INVENTION

In one aspect of the present invention is a method of selectively controlling the uniformity and/or rate of deposition of a metal or lithium in a sputter process by introducing a quantity of reactive gas over a specified area in the sputter chamber. This method is applicable to planar and rotating targets.

In another aspect of the present invention is a method of depositing a film or coating of lithium on a substrate comprising (i) placing a metallic target and a substrate in a chamber; and (ii) sputtering the target in an atmosphere having components designed to increase the rate of sputtering of a metal from the metallic target as compared with the sputtering rate of the metal from the metallic target in a standard inert atmosphere. In another embodiment, the reactive gas is introduced form an upstream process. In one embodiment of the present invention, the component for increasing the rate of sputtering is a reactive gas. In another embodiment of the present invention, the reactive gas is selected from the group consisting of oxygen, nitrogen, halogens, water vapor, and mixtures thereof. The lithium may be pure lithium metal, lithium doped with another metal, or the lithium may contain other compounds or impurities. It is also possible that the lithium itself may be an oxide or nitride or some other lithium-based compound.

Another aspect of the present invention is a method of depositing a film or coating of lithium on a substrate comprising (i) placing a target and a substrate in a chamber; and (ii) sputtering the target in an atmosphere comprising a reactive gas and an inert gas.

Another aspect of the present invention is a method of depositing a film or coating of lithium on an electrode of an electrochromic device comprising (i) placing a lithium target and an electrochromic device in a chamber; and (ii) sputtering the target in an atmosphere comprising a reactive gas and an inert gas.

Another aspect of the present invention is a process of monitoring and/or modifying the uniformity and/or rate of deposition of lithium on a substrate comprising the steps of (i) measuring a parameter which is a surrogate for the rate of sputtering of lithium; (ii) comparing the measured parameter with a predetermined value or set-point to determine if the rate of sputtering needs to be changed; and (iii) adjusting the atmosphere within at least a portion of the sputtering chamber to change the rate of sputtering. In one embodiment, the rate of sputtering is changed by introducing a reactive gas to the sputter chamber or a portion thereof.

Another aspect of the present invention is a sputter system comprising (i) a chamber configured for sputtering a planar or rotating target; (ii) one or more mixed gas manifolds in fluidic communication with the chamber; and (iii) reactive gas and inert gas sources in fluidic communication with the mixed gas manifolds.

In one embodiment of the present invention, the reactive gas is selected from the group consisting of oxygen, nitrogen, halogens, water vapor, and mixtures thereof.

In another embodiment of the present invention, the inert gas is selected from argon.

In another embodiment of the present invention, a ratio of the reactive gas to the inert gas is about 1:100 to about 100:1. In another embodiment, an amount of reactive gas added to the atmosphere or as part of the total gas flow ranges from about 0.01% to about 100% of the total gas flow.

In another aspect of the present invention is a method of depositing a film or coating of lithium on a substrate comprising (i) placing a lithium target and the substrate in a chamber; and (ii) sputtering the target in an atmosphere having components designed to increase a rate of sputtering of lithium as compared with a sputtering rate of lithium in an inert atmosphere. In another embodiment, the component designed to increase the rate of sputtering is selected from the group consisting of oxygen, nitrogen, halogens, water vapor and mixtures thereof.

In another aspect of the present invention is a method of depositing a film or coating of lithium on a substrate comprising (i) placing a lithium target and the substrate in a chamber; and (ii) sputtering the target in an atmosphere comprising a reactive gas and an inert gas. In another embodiment, the chamber is an evacuated chamber. In another embodiment, the chamber is at least partially evacuated of at least some of the upstream process components.

In another embodiment, the reactive gas is selected from the group consisting of oxygen, nitrogen, halogens, water vapor and mixtures thereof. In another embodiment, the reactive gas is oxygen. In another embodiment, the inert gas is selected from the group consisting of argon, helium, neon, krypton, xenon, and radon.

In another embodiment, the substrate is selected from the group consisting of a glass, a polymer, a mixture of polymers, a laminate, an electrode, a film comprising a metal oxide or a doped metal oxide, and an electrochromic device. In another embodiment, a ratio of the reactive gas to the inert gas is about 1:100 to about 100:1. In another embodiment, an amount of the reactive gas added to the atmosphere ranges from about 0.01% to about 10% of a total amount of gas within the atmosphere. In another embodiment, an amount of the reactive gas added to the atmosphere ranges from about 0.01% to about 7.5% of a total amount of gas within the atmosphere. In another embodiment, the reactive gas increases the rate of sputtering by about 1% to about 30%.

In another embodiment, the reactive gas is added to a portion of the atmosphere. In another embodiment, the reactive gas is added to an area of the sputtering chamber surrounding a particular portion of the target. In another embodiment, the particular portion of the target is an area of non-uniformity.

In another embodiment, the reactive gas is introduced from an upstream process. In another embodiment, the reactive gas introduced from an upstream process is oxygen. In another embodiment, in addition to the reactive gas added from the upstream process, additional quantities of the same or different reactive gas are introduced. In another embodiment, in addition to the reactive gas added from the upstream process, additional quantities of a same reactive gas is introduced. In another embodiment, in addition to the reactive gas added from the upstream process, additional quantities of a different reactive gas is introduced.

In another aspect of the present invention is a sputter system comprising (i) a chamber configured for sputtering a planar or rotating lithium target; (ii) one or more mixed gas manifolds in fluidic communication with the chamber; and (iii) reactive gas and inert gas sources in fluidic communication with the mixed gas manifolds. In another embodiment, the reactive gas is introduced into a portion of the chamber by at least one mixed gas manifold. In another embodiment, the portion of the chamber corresponds to a non-uniform portion of the target. In another embodiment, the reactive gas is selected from the group consisting of oxygen, nitrogen, halogens, water vapor and mixtures thereof. In another embodiment, a ratio of the reactive gas to the inert gas is about 1:100 to about 100:1. In another embodiment, the reactive gas is introduced into the chamber from an upstream process. The upstream process may be another sputter process, sputter chamber, or other deposition process/chamber. In another embodiment, additional reactive gas is added to the chamber. In another embodiment, in addition to the reactive gas added from the upstream process, additional quantities of a same reactive gas is introduced. In another embodiment, in addition to the reactive gas added from the upstream process, additional quantities of a different reactive gas is introduced.

In another aspect of the present invention is a process of monitoring or modifying the uniformity or rate of deposition of lithium on a substrate comprising the steps of (i) measuring a parameter which is a surrogate for the rate of sputtering of lithium; (ii) comparing the measured parameter with a predetermined value or set-point to determine if the rate of sputtering needs to be changed; and (iii) adjusting an atmosphere within at least a portion of the sputtering chamber to change a rate of sputtering. In another embodiment, the rate of sputtering is changed by introducing a reactive gas to at least a portion of the sputter chamber. In another embodiment, the reactive gas is introduced from an upstream process. In another embodiment, in addition to the reactive gas added from the upstream process, additional quantities of a same reactive gas is introduced. In another embodiment, in addition to the reactive gas added from the upstream process, additional quantities of a different reactive gas is introduced. In another embodiment, the parameter is a cross-talk level.

Contrary to that known in the art, Applicants have unexpectedly found that the rate of sputtering of lithium metal increases when a reactive gas is introduced in the sputter chamber or to an area in a sputter chamber. This is an unexpected result, since it is believed that essentially all other metals have a lower sputter rate in the presence of oxygen due to oxidation of the target surface and a resulting higher molecular bond strength and subsequent conversion of sputter energy into secondary electron emission. Indeed, U.S. Pat. No. 4,769,291 illustrates that the sputter deposition rate drops rapidly as the oxygen flow ratio increases. Applicants have also found that the lithium metal sputtered in the presence of oxygen did not behave as though it was oxidized on the substrate. In fact, it behaved exactly like lithium sputtered in a pure un-oxidized state.

### BRIEF DESCRIPTION OF THE DRAWINGS

FIG. 1 is a chart showing the rate of change of sputtering when a reactive gas is introduced.

FIG. 2 is a schematic view of a sputtering system.

FIG. 3 is a schematic view of a sputtering system.

FIG. 4 is a flowchart showing the operational sequence of a sputtering process.

### DETAILED DESCRIPTION

Applicants have discovered a method of selectively controlling the rate of sputtering of a lithium target (or metallic lithium target). Specifically, Applicants have discovered that the introduction of a reactive gas during sputtering results in an increase in the rate of sputtering and a concomitant increase in the rate of deposition of lithium on a substrate. Applicants have also discovered that the introduction of the reactive gas over a specified area of the sputtering chamber, target, or inert gas stream allows for a localized, and reversible, increase in the rate of sputtering corresponding to that area of the target where the reactive gas was introduced. Accordingly, it is believed that by monitoring the deposition of lithium on a substrate and modifying the then existing conditions within the sputter chamber in response to deviations in the monitored deposition, it is possible to continuously and selectively control the rate of sputtering along the entire sputter target or portions thereof.

The “then existing conditions” means the composition of any atmosphere within the sputter chamber. For example, this could mean a pure inert gas atmosphere or an atmosphere comprising a mixture of a reactive gas and an inert gas. Those skilled in the art will recognize that the then existing conditions could be modified by (i) introducing a quantity of a reactive gas or mixture of reactive gases (to increase the concentration of a particular reactive gas or the total concentration of reactive gases); (ii) introducing a quantity of a inert gas or mixture of inert gases (to increase the concentration of a particular inert gas or the total concentration of inert gases); or (iii) introducing a mixture of a reactive gas and an inert gas, where the introduced mixture has a different reactive gas concentration than that existing in the chamber (i.e. prior to modification).

As used herein, the term “introduction” means an addition or change in the concentration of a gas (or mixture of gases). A gas may be introduced by any means known in the art. For example, an additional quantity of a reactive gas could be added to the sputter chamber or to an inert gas stream by increasing the flow of that specific reactive gas (or mixture of gases) into the sputter chamber or gas stream (where, for example, the quantity of gas added can be determined by monitoring an attached flow meter or other mass flow controller).

As used herein, the term “sputtering chamber” may refer to the entire sputter chamber, a portion thereof, or an area surrounding a particular area of the sputter target.

As used herein, the term “total gas flow” refers to a quantity or rate of a gas flowing through a portion of the sputter system. For example, it could refer to an amount of gas flowing through a particular manifold or over a specific portion of the sputter target.

In one embodiment of the present invention is a method of depositing a film or coating of lithium on a substrate comprising (i) placing a lithium target and a substrate in an evacuated chamber; and (ii) sputtering the target in an atmosphere having components designed to increase the rate of sputtering of lithium as compared with the sputtering rate of lithium in a standard inert atmosphere. In some embodiments, the lithium target is a metallic target having a purity of at least about 95%. The target can be a planar or rotating target.

In some embodiments, the substrate is selected from an, an insulating material, glass, plastic, an electrode, an electrochromic layer, a layer comprising a metal oxide, a dpoed metal oxide, or a mixture of metal oxides, or an electrochromic device.

In some embodiments, the components designed to increase the rate of sputtering are reactive gases. Reactive gases suitable for use in the present invention include oxygen, nitrogen, halogens, water vapor, and mixtures thereof. In a preferred embodiment, the reactive gas is oxygen. Those skilled in the art will be able to select a particular reactive gas, or mixture thereof, to provide for the desired rate of sputtering of lithium. Inert gases suitable for use in the present invention include argon, helium, neon, krypton, xenon and radon. In preferred embodiments, the inert gas is argon.

The amount of reactive gas introduced to the sputtering chamber or the inert gas stream depends on the type of reactive gas introduced, the desired rate of sputtering, and where the reactive gas is introduced. In general, the amount of reactive gas introduced ranges from about 0.01% to about 100% of the total gas flow or the total atmosphere of the sputter chamber. In some embodiments, the amount of reactive gas introduced ranges from about 0.01% to about 10% of the total gas flow or the total atmosphere of the sputter chamber. In other embodiments, the amount of reactive gas introduced ranges from about 0.01% to about 7.5% of the total gas flow or the total atmosphere of the sputter chamber. In yet other embodiments, the amount of reactive gas introduced ranges from about 0.01% to about 5% of the total gas flow or the total atmosphere of the sputter chamber. In yet further embodiments, the reactive gas is oxygen and the amount of oxygen introduced ranges from about 0.01% to about 7.5% of the total gas flow or the total atmosphere of the sputter chamber.

It is believed that there is a relationship between the amount of reactive gas in the sputter chamber and the rate of sputtering of lithium. For example, in experiements it has been determined that adding about 1% of oxygen to a region of the sputter chamber resulted in an approximately 10% increase in sputter rate in that area of the sputter chamber. Further, and as will be discussed further herein, this has found to be reversible, and hence controllable so that the addition of Oxygen can be used to increase the sputter rate, or introduced locally to influence the uniformity of sputtering in the process zone by locally altering the sputter rate.

In some embodiments, the reactive gas is added to the entire atmosphere within the sputter chamber. Those skilled in the art will recognize that one method of increasing the rate of sputtering is by increasing the power of the sputter system. Increasing the power of the system, however, often results in undesirable melting or warping of the target and concomitant increases in energy costs. Without wishing to be bound by any particular theory, it is believed that by introducing a reactive gas during sputtering allows for an increase in the rate of sputtering, without damage to the target or the additional energy requirements associated with increasing system power. It is also believed that sputtering systems could be run at a lower power level and still achieve the desired sputter rate through introduction of an appropriate concentration of reactive gas at an appropriate rate.

In other embodiments, the reactive gas is introduced over a specified area of the sputter chamber or to an area surrounding a particular portion of the target. In this way it is believed that the rate of sputtering is increased locally relative to the area in which the reactive gas is introduced. In yet other embodiments, the reactive gas is introduced to an area of the sputter target which is believed to be non-uniform, uneven, or inconsistent (collectively referred to as “non-uniform”). In even further embodiments, the reactive gas is introduced to an area of the sputter target which corresponds to a non-uniform area of the substrate.

Without wishing to be bound by any particular theory, it is believed that the uniformity of sputtered lithium on a substrate can be controlled by locally increasing the rate of sputtering. As such, it is believed that locally increasing the rate of sputtering could be advantageously applied when the supplied target is non-uniform. Moreover, it is believed that locally increasing the rate of sputtering could be advantageously applied when the wear on the target is uneven, as could be caused by degraded or improperly positioned magnets, or when an inert gas flow in the sputter chamber is not evenly distributed. Those skilled in the art will recognize that sputtering from a non-uniform target could cause irregularities in any sputtered film or coating on the substrate. In addition, local introduction of a reactive gas could be used to control uniformity in the instance where a neighboring zone uses a reactive gas and there is uncontrolled gas flow (cross-talk) to the lithium sputter zone.

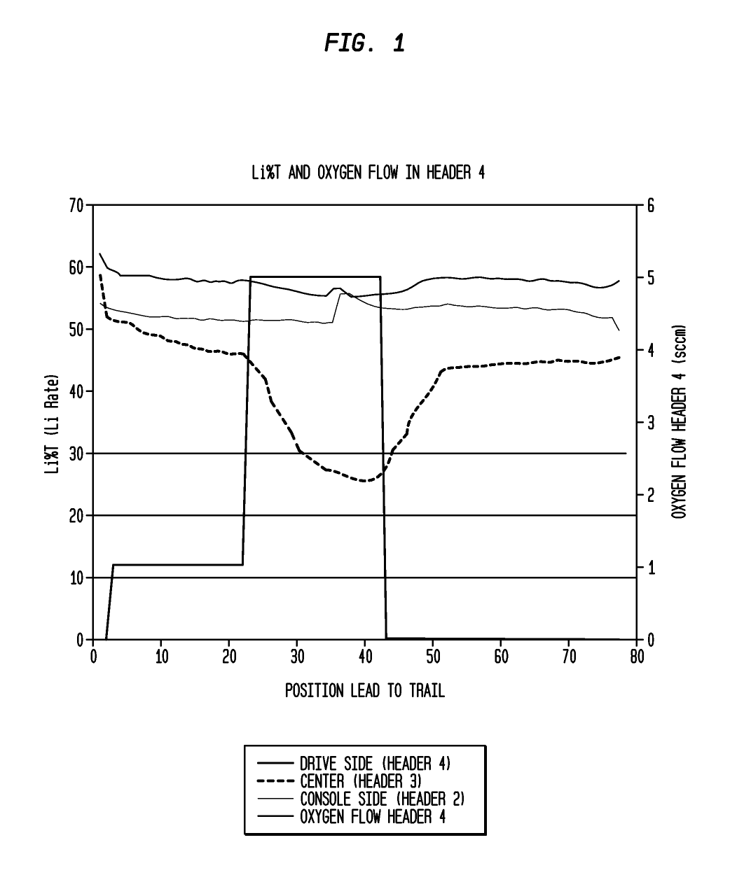

As demonstrated in FIG. 1, the introduction of a reactive gas increases the rate of sputtering locally, i.e. within an area near or surrounding that portion of the target where the reactive gas was introduced. For example, when oxygen, a reactive gas, was introduced at Header 4, the rate of sputtering (determined by monitoring transmissivity through the substrate) local to that header was increased, while the rate of sputtering at other headers (Header 3 and Header 2) was not substantially affected.

Moreover, Applicants have determined that the increased rate of sputtering influenced by the introduction of a reactive gas is reversible, i.e. when the amount of reactive gas introduced is reduced or stopped, the rate of sputtering slows or returns, respectively, to sputter rates consistent with those observed prior to introduction of a reactive gas. For example, FIG. 1 demonstrates that when the gas stream introduced at Header 4 either contained about 1% oxygen or about 5% oxygen, the rate of sputtering near or surrounding that portion of the sputtering target increased (as indicated by the decrease in the percent transmission). When the flow of oxygen gas was stopped, the rate of sputtering at Header 4 recovered to about those sputter rates existing prior to the introduction of the reactive gas.

It is believed that the process of the present invention also has the benefit that the prior removal of a reactive gas used in an upstream process step would not be necessary if the lithium sputtering process itself called for the presence of at least a portion of that reactive gas. As such, in some embodiments the quantity of a reactive gas added to the sputter chamber is that amount used in a previous coating step. Where necessary, additional quantities of reactive gas or other reactive gases could be added to further increase the rate of sputtering, either along the entire target or locally at one or more mixed gas manifolds. Similarly, to decrease the overall or local rates of sputtering, such as when too much reactive gas is present from an upstream process (causing a higher than desired sputter rate), additional quantities of one or more inert gases could be added back into the entire chamber or locally at one or more mixed gas manifolds.

Similarly, it is believed that it would not be necessary to remove a reactive gas from the lithium sputtering step if a subsequent downstream step called for the presence of at least a portion of that reactive gas. It is believed that adequate isolation could be achieved using more conventional means such as pumps and tunnels. It is believed that this would allow for quicker processing of a substrate along a manufacturing line. It is believed that the use of locks could be at least partially avoided.

Another aspect of the present invention is a sputter system comprising (i) a chamber configured for containing a lithium target and a substrate; (ii) one or more manifolds in fluidic communication with the chamber; and (iii) reactive gas and inert gas sources in fluidic communication with the manifolds.

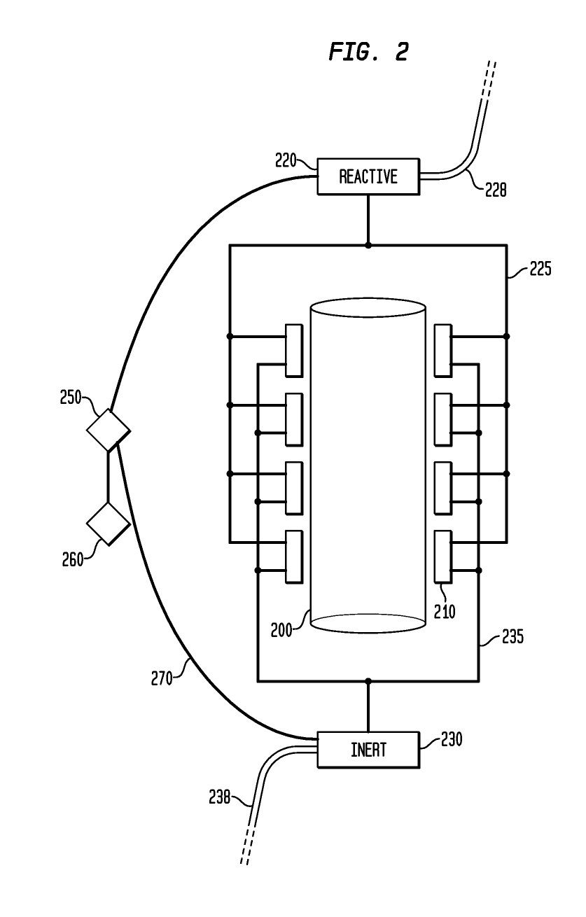

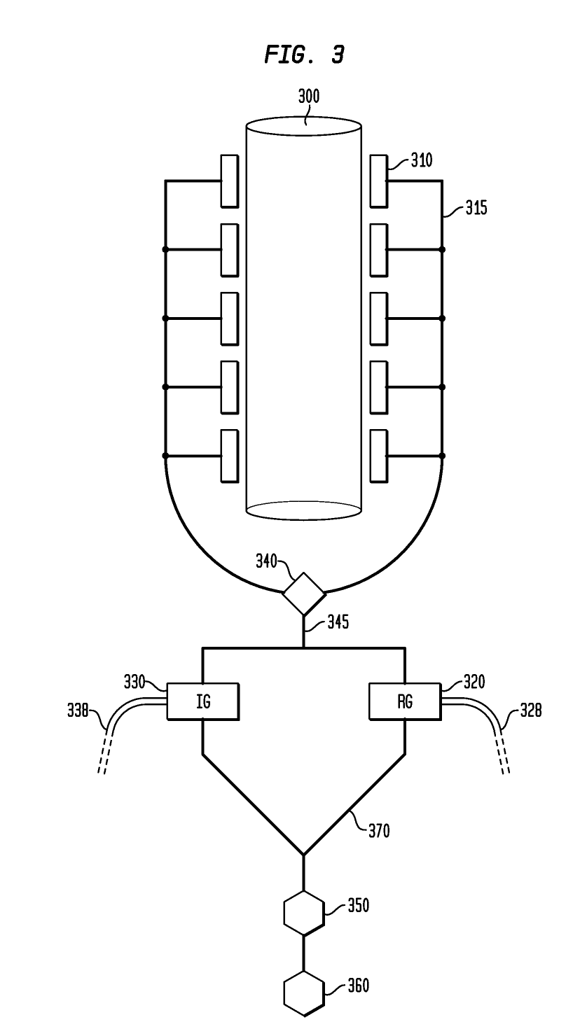

In one embodiment of the invention, and as depicted in FIGS. 2 and 3, the sputtering system contains a plurality of mixed gas manifolds 210 or 310 in fluidic communication with the sputter chamber. In some embodiments, the mixed gas manifolds 210 or 310 comprise inlets and outlets to allow transport of inert and/or reactive gases from supply lines to the sputter chamber 200 or 300. The manifolds allow for a constant stream of gas to be introduced into the sputter chamber.

The mixed gas manifolds 210 or 310 may be spaced at equal intervals or randomly across the perimeter of the chamber. In some embodiments, the mixed gas manifolds are equally spaced as shown in FIG. 2 and FIG. 3. Without wishing to be bound by any particular theory, it is believed that by providing equally spaced mixed gas manifolds, it is possible to provide for an even distribution of gas to the atmosphere within the chamber or to an area surrounding or adjacent to the lithium target 200 or 300. Any number of manifolds may be added to provide for the desired control of sputtering.

In some embodiments, such as depicted in FIG. 2, each manifold 210 is connected to an inert gas manifold supply line 235 and a reactive gas manifold supply line 225. The reactive and inert gas manifold supply lines 225 and 235 carry reactive gas or inert gas, respectively, at predetermined flow rates to each mixed gas manifold 210. Flow meters or pressure sensors can be present at the inlets to monitor gas flow rates.

In some embodiments, the manifolds 210 and inert gas manifold supply lines 235 allow for a constant stream of inert gas to be supplied to the chamber. Predetermined quantities of reactive gas could be introduced at predetermined rates into the inert gas stream from reactive gas manifold supply lines 225 as needed and as described herein. In some embodiments, the reactive and inert gas manifold supply lines 225 and 235 are connected to inlets of the mixed gas manifolds 210. Any inlet suitable for introduction of a reactive gas into the inert gas stream is suitable for this purpose.

In some embodiments, each mixed gas manifold 210, reactive gas manifold supply line 225, and/or inert gas manifold supply line 235 contains one or more mass flow controller (MFC) or valves (used interchangeably herein) which operate to selectively introduce an inert or reactive gas at a predetermined rate into the chamber. Those skilled in the art will be able to select appropriate MFCs, valves, or other control mechanisms, for this purpose. Each MFC may be selectively and independently operated to allow for control of the quantity of gas introduced, the location of the introduction of the gas relative to the sputter target, and the rate of release of the gas. The system may have any number of mixed gas manifolds 210 and corresponding independently controlled MFCs depending on the level of control desired.

In some embodiments, MFCs are present at (i) the junction of a mixed gas manifold inlet and the reactive gas manifold supply line 225, and (ii) at the junction of a mixed gas manifold inlet and the inert gas manifold supply line 235. When commanded (by a computer or a human), these MFCs can be controlled to introduce predetermined quantities of a gases at predetermined rates. Those skilled in the art will recognize that the MFC at each mixed gas manifold inlet can be regulated together or independently to regulate gas flow at each mixed gas manifold. For example, if it is determined that the rate of sputtering needs to be increased at a central point on the lithium target, a manifold at or around that central point could be commanded to introduce a stream of inert gas and a predetermined quantity of a reactive gas.

The reactive gas manifold supply line 225 is connected to and in fluidic communication with a reactive gas manifold 220. Likewise, the inert gas manifold supply line 235 is connected to and in fluidic communication with an inert gas manifold 230. Those skilled in the art will recognize that the inert gas manifold 230 and reactive gas manifold 220 are each suitable for mixing predetermined amounts of different inert or reactive gases, respectively.

In some embodiments, an inlet of the inert gas manifold 230 is connected to an inert gas supply line 238 (which is itself connected to one or more inert gas sources) so as to deliver one or more inert gases to the inert gas manifold 230. In some embodiments, an outlet of the inert gas manifold 230 is connected to the inert gas manifold supply line 235.

Likewise, in some embodiments, an inlet of a reactive gas manifold 220 is connected to one or more reactive gas supply lines 228 where, preferably, each reactive gas supply line is connected, independently, to a different reactive gas source. In some embodiments, an outlet of the reactive gas manifold 220 is connected to a reactive gas manifold supply line 225.

In other embodiments, each of the inert gas 230 and reactive gas 220 manifolds may contain one or more MFCs, preferably at both their inlets and outlets, such that each of the inert gas 230 or reactive gas 220 manifolds may selectively be placed in fluidic communication with the respective manifold supply lines 235 and 225, inert gas supply lines 238, or reactive gas supply lines 228. These MFCs are each independently controlled by a computer 250 and/or interface module 260.

By way of example, during operation, an inert gas is continuously introduced through each manifold 210 to the sputtering chamber 200 at a predetermined rate. When necessary, a reactive gas can be introduced to the inert gas stream at a particular manifold to increase the rate of sputtering locally to the point of introduction of that reactive gas. Meanwhile, the other manifolds, which do not receive reactive gas, would continue to supply inert gas at the predetermined rate. When it is no longer necessary for a particular portion of the target to receive reactive gas, the manifold introducing reactive gas would revert to only supplying the predetermined flow of inert gas. The supply of reactive gas could be tapered off to gradually reduce the rate of sputtering or completely stopped.

In other embodiments, such as depicted in FIG. 3, each mixed gas manifold 310 is connected to and in communication with mixed gas manifold supply lines 310. In some embodiments, the mixed gas supply lines 315 are connected to inlets of the mixed gas manifolds 310. The mixed gas manifold supply lines 315 carry a predetermined gas, or mixture of gases, at a predetermined flow rate to each mixed gas manifold 310. In some embodiments, each mixed gas manifold 310 has its own dedicated manifold supply line 315. In other embodiments, each mixed gas manifold 310 shares the same mixed gas supply line 315. Those skilled in the art will be able to incorporate as many mixed gas manifolds 310 and mixed gas manifold supply lines 315 as needed to achieve the desired level of control over the sputter process as described herein.

In some embodiments, each mixed gas manifold 310 and/or mixed gas manifold supply line 315 contains one or more MFCs which operate independently to selectively introduce a predetermined gas at a predetermined rate into the chamber. Those skilled in the art will be able to select appropriate MFCs for this purpose. The system may have any number of mixed gas manifolds 310 and corresponding independently controlled MFCs depending on the level of control desired.

In some embodiments, a single MFC is present at the junction of a mixed gas manifold inlet and the mixed gas manifold supply line 315. When commanded (by a computer or a human), this MFC can open to introduce a predetermined quantity of a predetermined gas at a predetermined rate. Those skilled in the art will recognize that the MFC at each mixed gas manifold inlet can be regulated together or independently to regulate gas flow at each mixed gas manifold.

In some embodiments, the mixed gas manifold supply lines 315 are connected to an optional gas mixing chamber 340, whereby predetermined amounts of inert and/or reactive gas are mixed and/or held prior to passing to the mixed gas manifold supply lines 315. In some embodiments, the gas mixing chamber 340 contains one or more MFCs on both the inlet and outlet of the mixing chamber such that fluidic communication between the mixed gas manifold supply lines and mixed gas supply lines 345 may be independently controlled. The mixing chamber 340 may contain an impeller to assist in mixing gases.

In other embodiments, the mixed gas manifold supply lines 315 are directly connected to mixed gas supply lines 345, which in turn are in communication with inert gas 330 and reactive gas 320 manifolds.

In some embodiments, an inlet of the inert gas manifold 330 is connected to an inert gas supply line 338 (which is itself connected to one or more inert gas sources) so as to deliver one or more inert gases to the inert gas manifold 330. In some embodiments, an outlet of the inert gas manifold is connected to a mixed gas supply line 345.

Likewise, in some embodiments, an inlet of a reactive gas manifold 320 is connected to one or more reactive gas supply lines 328 where, preferably, each reactive gas supply line is connected, independently, to a different reactive gas source. In some embodiments, an outlet of the reactive gas manifold 320 is connected to a mixed gas supply line 345.

In other embodiments, each of the inert gas 330 and reactive gas 320 manifolds may contain one or more MFCs, preferably at both their inlets and outlets, such that each manifold may selectively be placed in fluidic communication with the respective mixed gas supply lines 345, inert gas supply lines 338, or reactive gas supply lines 328. These MFCs are each independently controlled by a computer 350 or a interface 360.

Other non-limiting control methods, known to those of skill in the art, which may be suitable for incorporation in the present device include pressure control, partial pressure control, and voltage control of the power supply. For example, a common embodiment would be to operate the cathode in pressure control. Since pressure is one variable that can influence rate, holding this constant by using a pressure gauge, such as a capacitance manometer, and using this measurement to control gas flow (by close-looping through a PLC, for example), is a means of providing increased process stability. In some embodiments, both argon and oxygen can be flowing, and the mass flow controllers will get an analog or digital signal to increase or decrease flow to keep the pressure constant while maintaining a predetermined flow ratio. Partial pressure control can be achieved similarly by using a residual gas analyzer (“RGA”) or other measurement device to provide partial pressure information. This would enable the partial pressure of argon and oxygen to be controlled independently.

The sputter pressure and gas flow is typically controlled using the equipment in the sputter chamber and the control system on the coater. Generally programmable logic controllers (“PLC”) or personal computer (“PC”) based control systems are used, with control software writtent to allow control for the pressure and gas flow distribution from an human-machine interface (HMI), and also via automatic cotrol through the use of process monitoring. Pressure can be measured using a variety of vacuum gauges such as capacitance manometers, ion gauges, thin film gauges, and the like. Pressure can be controlled by changing the flow rate of gas, increasing or reducing the pumping rate (by throttling, reducing pump rotation speed, or adding pump slits which can be adjusted). In one embodiment, the process is operated in a pressure control using the output of a capacitance manometer to provide control inputs to the MFCs controlling the gas flow.

The control of the lithium sputter rate is supplied using the optical method described herein, or other equipment such as crystal rate monitor, atomic absorption spectrum monitoring, or other methods known to those of skill in the art.

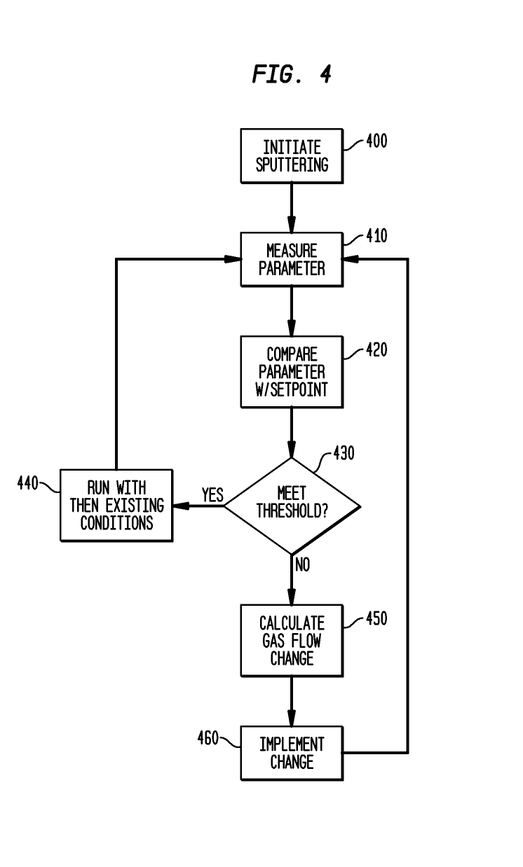

Another aspect of the present invention is a process of monitoring, and correcting if necessary, the uniformity and/or rate of deposition of lithium on a substrate, as depicted in FIG. 4. The uniformity and/or rate of deposition of lithium can be monitored by measuring 410, for example, the thickness of the lithium thin film coating produced on the substrate, the transmissivity of light passing through the coated substrate, and/or the rate at which the coated substrate leaves the sputtering chamber. In preferred embodiments, the rate of sputtering is measured by monitoring the transmission of light through the deposited lithium. It is believed that as the rate of lithium sputtering increases, and hence the amount of lithium deposited increases, transmission of light through the substrate is reduced. Any of these measured parameters 410 may be used as a surrogate to determine the rate of sputtering and/or the uniformity of the deposited film or coating on the substrate.

The measured parameter is then compared to a predetermined value or set-point 420 (or, in some instances, a range of values). As will be appreciated by those of skill in the art, the predetermined value or set-point may be different for different types of substrates, for different substrate applications, or for different types of lithium targets.

A computer or human then will determine whether the measured parameter meets the predetermined value or set-point at step 430. If the measured parameter is sufficient, i.e. meets the predetermined criteria, the process is run with the then-existing conditions within the sputter chamber 440. However, if the measured parameter is insufficient, i.e. does not meet the predetermined criteria, the process is then modified by changing one or more constituent parts of then existing conditions within the chamber or in the inert gas flow stream. A computer or human would calculate the amount, type, and/or rate of delivery of a reactive gas necessary o effect a change in the rate of sputtering 450. The reactive gas would then be introduced to implement the change 460. The cycle would continue and be repeated as necessary.

In some embodiments, an algorithm 450 is used to determine the optimum atmospheric conditions with the sputter chamber (either along the entire chamber or local to any portion of the target) or in an inert gas stream, i.e. an algorithm is used to determine the ratio of reactive gas to inert gas in the chamber or inert gas stream to optimize the rate of sputtering. For example, a linear equation may be used which would add or subtract 0.1% of oxygen flow locally for each 1% of lithium rate adjustment required. In addition, the algorithm may account for globally adjusting the oxygen flow among several manifolds simultaneously to maintain and overall uniformity and sputter rate. This algorithm may also include a power adjustment as necessary to keep the overall rate under control. In some embodiments, a computer or human will then determine the best way to implement the change 460 to modify the then existing conditions with the sputter chamber, i.e. the best way to alter the gas flow at a particular manifold or inert gas stream, the ratios of reactive/inert gas needed, and/or the components of the reactive gas/inert gas mixture need.

By way of example, if the measured transmissivity of a substrate falls below a predetermined set-point, the sputter system of the claimed invention will respond by introducing an amount of reactive gas to correct for the deficiency. If, for instance, it was determined that the uniformity of the deposited lithium in a center portion of the substrate was insufficient, a quantity of reactive gas sufficient to implement an increase in sputtering rate, would be delivered to that portion of the lithium target corresponding to the non-uniform portion of the substrate.

The measured parameter 410 may be monitored continuously or may be monitored in predetermined intervals. In this way, it is possible to continuously adjust the then existing conditions within the sputter chamber or in the inert gas stream to provide a coated substrate having a uniform, predetermined thickness or to deposit a coating on a substrate at a given rate.

An example of an automated control system would be an optical monitoring system operated in conjunction with the coater PLC control system. This device would monitor the coating uniformity, and the information would be processed using an algorithm as described above. This information would then be sent to the PLC, and used to adjust the MFC flow parameters, power settings, pressure, or other control output of the system.

Although the invention herein has been described with reference to particular embodiments, it is to be understood that these embodiments are merely illustrative of the principles and applications of the present invention. It is therefore to be understood that numerous modifications may be made to the illustrative embodiments and that other arrangements may be devised without departing from the spirit and scope of the present invention as defined by the appended claims.

1. A method of depositing a film or coating of lithium on a substrate comprising (i) placing a lithium target and said substrate in a chamber; and (ii) sputtering said target in an atmosphere having components designed to increase a rate of sputtering of lithium as compared with a sputtering rate of lithium in an inert atmosphere.

2. The method of claim 1, where said component designed to increase said rate of sputtering is selected from the group consisting of oxygen, nitrogen, halogens, water vapor and mixtures thereof.

3. A method of depositing a film or coating of lithium on a substrate comprising (i) placing a lithium target and said substrate in a chamber; and (ii) sputtering said target in an atmosphere comprising a reactive gas and an inert gas.

4. The method of claim 3, wherein said reactive gas is selected from the group consisting of oxygen, nitrogen, halogens, water vapor and mixtures thereof.

5. The method of claim 4, wherein said reactive gas is oxygen.

6. The method of claim 3, wherein said inert gas is selected from the group consisting of argon, helium, neon, krypton, xenon, and radon.

7. The method of claim 3, wherein said substrate is selected from the group consisting of a glass, a polymer, a mixture of polymers, a laminate, an electrode, a film comprising a metal oxide, and an electrochromic device.

8. The method of claim 3, wherein a ratio of said reactive gas to said inert gas is about 1:100 to about 100:1.

9. The method of claim 3, wherein an amount of said reactive gas added to said atmosphere ranges from about 0.01% to about 10% of a total amount of gas within said atmosphere.

10. The method of claim 3, wherein an amount of said reactive gas added to said atmosphere ranges from about 0.01% to about 7.5% of a total amount of gas within said atmosphere.

11. The method of claim 3, wherein said reactive gas increases the rate of sputtering by about 1% to about 30%.

12. The method of claim 3, wherein said reactive gas is added to a portion of said atmosphere.

13. The method of claim 3, wherein said reactive gas is added to an area of said sputtering chamber surrounding a particular portion of said target.

14. The method of claim 13, wherein said particular portion of said target is an area of non-uniformity.

15. The method of claim 3, wherein said reactive gas is introduced from an upstream process.

16. A sputter system comprising (i) a chamber configured for sputtering a planar or rotating lithium target; (ii) one or more mixed gas manifolds in fluidic communication with said chamber; and (iii) reactive gas and inert gas sources in fluidic communication with said mixed gas manifolds.

17. The system of claim 16, wherein said reactive gas is introduced into a portion of said chamber by at least one mixed gas manifold.

18. The system of claim 17, wherein said portion of said chamber corresponds to a non-uniform portion of said target.

19. The system of claim 16, wherein said reactive gas is selected from the group consisting of oxygen, nitrogen, halogens, water vapor and mixtures thereof.

20. The system of claim 16, wherein a ratio of said reactive gas to said inert gas is about 1:100 to about 100:1.

21. The system of claim 16, wherein said reactive gas is introduced into said chamber from an upstream process.

22. The system of claim 21, wherein additional reactive gas is added to said chamber.

23. The system of claim 22, wherein said additional reactive gas added to said chamber is different than said reactive gas introduced from said upstream process.

24. A process of monitoring or modifying the uniformity or rate of deposition of lithium on a substrate comprising the steps of (i) measuring a parameter which is a surrogate for the rate of sputtering of lithium; (ii) comparing the measured parameter with a predetermined value or set-point to determine if the rate of sputtering needs to be changed; and (iii) adjusting an atmosphere within at least a portion of the sputtering chamber to change a rate of sputtering.

25. The process of claim 24, where said rate of sputtering is changed by introducing a reactive gas to at least a portion of said sputter chamber.

26. The process of claim 24, wherein said reactive gas is introduced from an upstream process.

27. The process of claim 24, wherein said parameter is a cross-talk level.
